(19) United States
(12) Patent Application Publication
(10) Pub. No.: US 2009/0038083 A1
(43) Pub. Date: Feb. 12, 2009

(54) Compositions for treating fabric

(76) Inventors: Brian Joseph Roselle, Fairfield, OH (US); Freddy Arthur Barnabas, West Chester, OH (US); Janet Sue Littig, Hamilton, OH (US); Helen Frances O'Connor, Cincinnati, OH (US); Gayle Marie Frankenbach, Cincinnati, OH (US)

Correspondence Address: THE PROCTER & GAMBLE COMPANY;Global Legal Department - IP, Sycamore Building - 4th Floor, 299 East Sixth Street, CINCINNATI, OH, 45202, US

(21) Appl. No.: 12/283,575

(22) Filed: Sep. 12, 2008

Related U.S. Application Data
(63) Continuation-in-part of application No. 12/008,427, filed on Jan. 11, 2008.
Application No. 12/008,427 is a continuation-in-part of application No. 12/008,504, filed on Jan. 11, 2008.
(60) Provisional application No. 60/993,765, filed on Sep. 14, 2007.
(60) Provisional application No. 61/130,913, filed on Jun. 4, 2008.
(60) Provisional application No. 60/879,888, filed on Jan. 11, 2007.

(51) Int. Cl. D06L 1/04; C11D 17/08; G01R 29/12

(52) U.S. Cl. 8/142; 510/341; 8/137; 324/457

(57) ABSTRACT

Compositions for treating fabric. The compositions of the present invention may be used to improve various properties of fabrics such as the olfactory perception and/or appearance of the fabric without requiring that the fabrics be put through an entire standard laundry process. Methods of treating the fabrics are also disclosed.

### CROSS REFERENCE TO RELATED APPLICATIONS

This application claims the benefit of U.S. Provisional Application Serial No. 60/993,765 filed on Sep. 14, 2007 (Attorney Docket No. 10907P) and U.S. Provisional Application Ser. No. 61/130,913 filed on Jun. 4, 2008 (Attorney Docket No. 10907P2) and is a continuation-in-part of U.S. application Ser. No. 12/008,427 filed on Jan. 11, 2008 (Attorney Docket No. 10679) which claims the benefit of U.S. Provisional Application Ser. No. 60/879,888 filed on Jan. 11, 2007 (Attorney Docket No. 10679P) and is also a continuation-in-part of U.S. application Ser. No. 12/008,504 filed on Jan. 11, 2008 (Attorney Docket No. 10680) which claims the benefit of U.S. Provisional Application Ser. No. 60/878,838 filed on Jan. 11, 2007 (Attorney Docket No. 10680P).

### FIELD OF THE INVENTION

The present invention relates to fabric care compositions and methods for treating fabrics in order to improve various properties of fabrics, in particular, restoration or improvement of the olfactory perception via malodor reduction or freshening and/or appearance restoration via wrinkle removal in wrinkled fabrics, particularly clothes, to make them suitable for wear without having to put them through a standard laundry process.

### BACKGROUND OF THE INVENTION

Normal wearing, and in some cases the process of laundering and storing fabrics, especially clothing, can result in fabrics that are no longer presentable or acceptable to be worn by the owner, especially from an olfactory and visual standpoint. As a result, there has been a long-felt need to find a “refresher” product that is simple and easy to use for the purpose of treating fabrics, particularly articles of clothing, that are not clean/fresh smelling and/or are not visually appealing, especially from a wrinkle or static standpoint, so as to restore the fabrics to a wearable condition without having to put them through the standard, time consuming laundry process of using a washing machine and dryer.

Various compositions are disclosed in the prior art as wrinkle control compositions. Commercially available wrinkle control compositions include those which tend to rely on silicone-containing materials to enable wrinkle removal. These commercial compositions include those that are applied to fabric from a spray dispenser.

The drawbacks of these compositions are that they do not include sufficient water soluble quaternary surfactant microemulsions which Applicants have found useful for quickly producing superior wrinkle removal and appearance restoration of worn or wrinkled fabrics.

The present invention relates to stable, preferably well dispersed, more preferably translucent, and even more preferably clear, quaternary microemulsion fabric refreshing compositions, fabric refreshing methods, and articles of manufacture that use such fabric refreshing compositions. The present invention relates to fabric refresher products comprising water soluble quaternary ammonium compounds (“water soluble quats”). It has been surprisingly found that a mixture of water, water soluble quats and a substantially water insoluble oil mix can form a microemulsion that provides desired benefits of wrinkle, malodor, and static reduction.

### SUMMARY OF THE INVENTION

The fabric refreshing compositions of the present invention include:
A. Water added as the balance of the ingredients listed below. Typically water may be added at a level from about 30% to about 99.9%;
B. A water soluble quaternary ammonium surfactant, wherein the typical minimum levels of the water soluble quaternary agent included in the composition are at least about 0.01%, preferably at least about 0.05%, more preferably at least about 0.1% while typical maximum levels of water soluble quaternary agent are up to about 20%, preferably less than about 10%, and more preferably less than about 3% and generally in the range of about 0.2% to about 1.0%;
C. A substantially water insoluble oil component or oil mix, wherein the oil components may have a clogP of >1. Typically the minimum levels of the oil component included in the composition are at least about 0.001%, preferably at least about 0.005%, and even more preferably at least about 0.01% while typical maximum levels of oil components are up to about 5.0%, preferably less than about 3%, more preferably less than 1.5%, and generally in the range of about 0.05% to about 1%;
D. Optionally, to augment the desired physical properties, an effective amount of nonionic surfactant may be added. Typically the minimum levels of the nonionic surfactant when used are at least about 0.01%, preferably at least about 0.05%, and more preferably at least about 0.1% wherein typical maximum levels of nonionic surfactant are up to about 5%, preferably about 3% or less, and more preferably about 1.5% or less.
E. Optionally, a buffering agent may be added in an effective amount to increase the resistance of pH change of the composition, wherein when used at least about 0.01% of a buffering agent is added, preferably at least about 0.05% is added, and more preferably at least about 0. 1% is added, while typical maximum levels of the buffering agent are up to about 3%, preferably less than about 1.5%, and more preferably less than about 0.5%.
F. Optionally, an effective amount of an odor control agent to provide additional malodor capturing/sequestering effects may be used, wherein when used said odor control agent is added in a minimum amount of about 0.01%, preferably at least about 0.1%, and more preferably at least about 0.2%, while typical maximum levels of the odor control agent are up to about 5%, preferably less than about 3%, and more preferably less than about 2%;
G. Optionally, an antimicrobial agent in an effective amount may be used to kill, or reduce the growth of microbes, wherein when used the antimicrobial agent is typically used at minimum amount of at least about 0.001%, preferably at least about 0.002%, and more preferably at least about 0.005%, while typical maximum levels of the antimicrobial agent are up to about 0.5%, preferably less than about 0.2%, and more preferably less than about 0.1%;
H. Optionally, an effective amount of a pH adjustment agent wherein the pH adjustment agent which may be used to achieve a pH of from about 3 to about 11, preferably from about 4 to about 10, and more preferably from about 5 to about 9;
I. Optionally, an effective amount of a solubilized, water-soluble, antimicrobial preservative, especially when the antimicrobial active is not sufficient to act as a preservative. Typically the minimum amounts of these antimicrobial preservatives when used are at least about 0.001%, preferably at least about 0.002%, and more preferably at least about 0.005% while typical maximum amounts when used are up to about 0.5%, preferably less than about 0.2%, and more preferably less than about 0.1%; and
J. Optionally, other water soluble solvents, wherein typical minimum amounts of these water soluble solvents when used are at least about 0.05%, preferably at least about 0.1%, and more preferably at least about 0.2% while typical maximum amounts when used are up to about 8%, preferably less than about 5%, and more preferably less than about 3%;
   wherein it is desirable that the composition be essentially free of any material that would damage fabric under usage conditions.

In one non-limiting embodiment, the fabric refresher compositions described herein are incorporated into a spray dispenser to create an article of manufacture that can facilitate treatment of fabrics and/or surfaces with the refresher compositions at a level that is effective, yet is not readily discernible when dried on fabrics, with the exception of color fade restoration. The spray dispenser comprises manually activated and non-manual powered (operated) spray means and a container containing the fabric refresher composition. In one embodiment of the fabric refresher compositions described herein, an inert, non-volatile gas is used as a propulsion agent in an aerosol dispenser can.

In one embodiment, compositions of the present invention are delivered to a surface to be treated using a device that creates small diameter droplets of the compositions herein. Non-limiting examples of such devices include pressure sprayers, atomizers, and nebulizers. The selected device delivers compositions to fabric and other surfaces as very small particles (droplets) preferably having weight average diameter particle sizes (diameters) of from about 5 μm to about 300 μm, more preferably from about 10 μm to about 200 μm, and even more preferably from about 20 μm to about 150 μm.

### DETAILED DESCRIPTION OF THE INVENTION

The present invention relates to compositions for treating fabric. The present invention also relates to methods for making the compositions of the present invention. The present invention further relates to articles comprising the compositions of the present invention and methods of using the compositions of the present invention. Reference will now be made in detail to various embodiments of the present invention. All percentages, ratios, and proportions herein are on a weight basis unless otherwise indicated. Except as otherwise noted, all amounts including quantities, percentages, portions, and proportions, are understood to be modified by the word “about”, and amounts are not intended to indicate significant digits. Except as otherwise noted, the articles “a”, “an”, and “the” mean “one or more”.

As used herein, “comprising” means that other steps and other ingredients which do not affect the end result can be added. This term encompasses the terms “consisting of” and “consisting essentially of”. The compositions and methods/processes of the present invention can comprise, consist of, and consist essentially of the essential elements and limitations of the invention described herein, as well as any of the additional or optional ingredients, components, steps, or limitations described herein.

It should be understood that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

Also included herein is a qualitative method for indicating the prevention of static on fabrics by these compositions. Static or static electricity is an imbalance of electrical charge on the surface of fabrics. This typically occurs by “tribocharging” when fabric materials are brought into contact and then separated, electrons are exchanged by the materials, leaving one with a relative positive charge and the other with a negative charge. Friction between two surfaces can enhance this charge separation process and materials further separated on the “triboelectric series” tend to transfer electrons more efficiently.

It has been discovered that static presence on the surface of fabrics can be indicated by non contact AC voltage detectors. Non contact AC voltage detectors are used to detect AC voltage without connecting or contacting live AC electrical wires. These devices are designed to be held stationary in the proximity of an alternating electric field. For example, the common use is to place the probe of these devices into an AC power outlet to indicate the presence of AC voltage. The device is held stationary and it senses an alternating voltage and typically indicates voltage presence with sound or lights. It has been discovered that it is possible, and very effective, to have non contact AC voltage detectors indicate the presence of static on fabrics by moving the device over the surface of fabrics. Not wishing to be bound by theory, it is believed that having the device in motion over a non-uniform static field present on fabrics simulates an alternating electric field of AC line voltage. Typically the device is run over the fabric at a distance of less than about 12 inches and at a rate of about 1 ft/sec. The presence of static on the fabric is indicated by the meter in its normal way. Without static on fabric the meter will not indicated any voltage present. A preferred example of this technique utilizes a GREENLEE G-11 non-contact voltage detector distributed by Greenlee Textron of Rockford, Ill. Compositions described herein can both eliminate existing static present on fabrics as well as prevent static build up.

### Fabric Refreshing:

As discussed before, the present invention relates to methods and compositions for fabric refreshing that utilize, at least in an effective amount to restore fabrics that are not fresh, are malodored and/or are wrinkled.

Microemulsions are macroscopically homogeneous mixtures of oil, water, and surfactant which on the microscopic level consist of individual domains of oil and water separated by a monolayer of amphiphile. As used herein “amphiphile” refers to a compound possessing both hydrophilic and hydrophobic properties. Microemulsions have been used in oil recovery with microemulsions containing anionic surfactant and some small nonionic alcohol being evaluated extensively. There are a number of ways to describe a microemulsion, with the more common features describing them being 1) appearance, i.e. having a transparent to slightly opaque visual appearance, 2) intricate phase behavior, 3) ease of mixing and formation to produce a stable solution, 4) small particle size and large interfacial area per unit volume, 5) solubilization capacity of organic and aqueous phases, and 6) excellent wetting properties.

The focus of this work, however, uses a quaternary ammonium surfactant based microemulsion in a fabric context for wrinkle removal, malodor control, or static reduction. The key physical properties used to dimension these quaternary ammonium surfactant based microemulsions on fabric are particle size and fabric wetting power, with clear products preferred for aesthetics. It is desirable for these fabric treating microemulsion compositions that the oil in water particle size be small to facilitate penetration into the fabric fiber and to provide adequate stability. Additionally, small particle size can provide a degree of homogeneity and/or clarity for aesthetic purposes. As used herein the terms “homogeneous” and “stable” refer to compositions that are described as visually uniform in appearance for at least 48 hours after mixing or shaking. Preferably, the oil droplet particle size is about 300 nm or less, preferably about 100 nm or less, and most preferably about 50 nm or less. For the present invention, typical oil droplet particle sizes may range from about 1 nm to about 300 nm.

Not wishing to be bound by theory, it is thought that the specific surfactant and oil components and their molar ratios may be a determining factor in the creation of the microemulsion. Factors that contribute to achieving proper particle size are the solubility parameters of the constituents, their molecular size and molecular shape.

Further, not wishing to be bound by theory, it is thought that the highly effective wetting properties of the microemulsions of the present compositions help the composition penetrate fabrics, especially cotton, in a fast and thorough manner by more completely wetting capillaries and pores of cotton fibers thereby accessing more of the internal hydrogen bonds within the cellulose structure. Disrupting the hydrogen bonds that help hold wrinkles in place is important to wrinkle removal. Rapid penetration of the fabric structure also helps facilitate better wrinkle removal in concert with tensioning, especially if the tensioning is applied shortly after the composition is applied to the fabric. This rapid release provides positive reinforcement to consumers who may apply tension by tugging or pulling the fabric very soon after the composition is applied. In a similar manner, rapid wetting and spreading of the composition provides better coverage on the fabric and improves the efficiency of malodor reduction by better contacting malodor causing components that are to be neutralized or complexed. Efficient wetting and coverage on fabrics further facilitates the distribution of the quaternary surfactant over the fabric surface preventing static buildup on fabric surfaces especially in dry or low humidity environments.

The Wetting Index may be used to describe the wetting behavior of a given treatment composition. Of particular interest is the ability to wet cotton garments. The Wetting Index is a test that measures the wetting rate of a product composition on various fabrics. The test involves placing a drop of test product (water is the reference product) on a fabric sample and timing how long it takes for the drop of the product composition to fully penetrate the fabric surface. The Wetting Index is defined as the time in seconds it takes a water control to fully penetrate the surface divided by the time it takes the test product composition. A larger Wetting Index number indicates better wetting and can be thought of as representing how many times faster the product composition wets the fabric than the water. The Wetting Index of cotton is preferably 2 or greater, more preferably greater than 5, and most preferably greater than 9.

Another aspect of the present invention is the improvement in moisture management that can be achieved by pretreating fabrics with the compositions and allowing them to dry. In this case moisture management means the ability to better wick water into the treated fabrics versus those that receive no pretreatment. This improved wicking capability translates into the ability to transport water/perspiration away from the skin and into the fabric/garment that is in direct contact with the skin to speed drying and improve skin comfort.

For the purpose of the present invention the substantially water insoluble oil component is defined as having a calculated log P (“clogP”) of greater than one. The P value is a measurement of the octanol/water partition coefficient of the material of interest and is the ratio between its equilibrium concentrations in octanol and in water. Since the partition coefficients of the preferred ingredients of this invention have high values, they are more conveniently given in the form of their logarithm to the base 10, logP, which is known as the logP value. These values can be conveniently calculated to give a clogP value. The clogP value of many perfume ingredients has been reported; for example, the Pomona92 datatbase, available from Daylight Chemical Information Systems, Inc. (Daylight CIS), Irvine, Calif., contains many, clogP values along with citations to the original literature. However, the clogP values can also be calculated by the “CLOGP” program, available from Daylight CIS. The “clogP value” is typically determined by the fragment approach of Hansch and Leo: c.f. A. Leo, in Comprehensive Medicinal Chemistry, Vol. 4, C. Hansch, P. G. Sammens, J. B. Taylor and C. A. Ramsden, Eds., p. 295, Pergamon Press, 1990.

Another source of calculating logP values is through the Log P property predictor (CSLogP) distributed by ChemSilo LLC, Tewksbury, Mass., 01816.

### A. Composition

### Water Soluble Quaternary Ammonium Surfactant:

Typically, minimum levels of the water soluble quat included in the compositions of the present invention are at least about 0.01%, preferably at least about 0.05%, more preferably at least about 0.1% even more preferably at least about 0.2% by weight, based on the total weight of the composition. Typically maximum levels of water soluble quaternary agent included in the composition are up to about 20%, preferably less than about 10%, and more preferably less than about 3% based on the total weight of the composition. Typically, the agent is present in the composition in an amount of about 0.2% to about 1.0%.

Specifically, the preferred water soluble quaternary compounds are dialkly quaternary surfactant compounds. Suitable quaternary surfactants include, but are not limited to, quaternary ammonium surfactants having the formula:

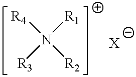

wherein R₁ and R₂ are individually selected from the group consisting of C₁-C₄ alkyl, C₁-C₄ hydroxy alkyl, benzyl, and —(C₂H₄O)ₓ H where x has a value from about 2 to about 5; X is an anion; and (1) R₃ and R₄ are each a C₆-C₁₄ alkyl or (2) R₃ is a C₆-C₁₈ alkyl, and R₄ is selected from the group consisting of C₁-C₁₀ alkyl, C₁-C₁₀ hydroxy alkyl, benzyl, and —(C₂H₄O)ₓH where x has a value from 2 to 5. A preferred asymmetric quaternary compounds for this invention are compounds where R3 and R4 are not identical, and preferably one is branched and the other one is linear.

An example of a preferred asymmetric quaternary compound is ARQUAD HTL8-MS where X is a methyl sulfate ion, R1 and R2 are methyl groups, R3 is a hydrogenated tallow group with <5% mono unsaturation, and R4 is a 2-ethylhexyl group. ARQUAD HTL8-MS is available from Akzo Nobel Chemical of Arnhem, Netherlands.

An example of a suitable symmetric quaternary compound is UNIQUAT 22c50 where X is a carbonate and bicarbonate, R1 and R2 are methyl groups, R3 and R4 are C10 alkyl groups. UNIQUAT 22c50 is a registered trademark of Lonza and in North America is available thru Lonza Incorporated of Allendale, N.J.

Another example of a suitable water soluble quaternary compound is BARQUAT CME-35 which is N-Cetyl Ethyl Morpholinium Ethosulfate available from Lonza and having the following structure:

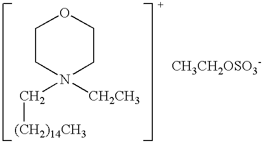

### Oil Component:

The oil component of the present invention represents a substantially water insoluble material that is incorporated into the composition by way of a microemulsion. Typically the minimum levels of the oil component included in the composition are at least about 0.001%, preferably at least about 0.005%, more preferably at least about 0.01%, and typically maximum levels of oil components are up to about 5%, preferably less than about 3%, more preferably less than 1.5%; with typical levels being in the range of about 0.05% to about 1%. The oil component can be a single component, but is typically a mixture and usually represents the incorporation of some benefit agent into the composition. Typically the oil component is a perfume made up a mixture of components, but can also be non-perfume materials such as substituted or unsubstituted hydrocarbons and the like. For spray products it is preferred that the oil component or mix be a liquid at room temperature for ease of incorporation into the composition and less potential for nozzle clogging on drying.

The oil components of the present invention are substantially water insoluble and form a microemulsion. Substantially water insoluble means the clogP of the ingredients are greater than about 1. A clogP of about 1 indicates that the component would tend to partition into octanol about 10 times more than water. Some preferred, but non-limiting, components in the oil mixture are branched hydrocarbons and perfumes when perfumes are used.

### Perfume:

The fabric refresher compositions described herein can also provide a “scent signal” in the form of a pleasant odor which provides a freshness impression to the treated fabrics. The scent signal can be designed to provide a fleeting or longer lasting perfume scent. When perfume is added as a scent signal, it is added only at very low levels, e.g., from about 0.001% to about 0.01% by weight of the usage of the composition.

Perfume can also be added as a more intense odor in product and on fabrics. When higher levels of fabric freshness are preferred, relatively higher levels of perfume can be added. These levels may be minimally from about 0.005%, preferably at least about 0.01%, more preferably at least about 0.1% and typically maximum levels of up to about 5%, preferably less than about 3%, and more preferably less than about 1%.

Suitable perfumes, perfume ingredients, and perfume carriers are disclosed in U.S. Pat. No. 5,500,138 issued to Bacon et al. on Mar. 19, 1996 and U.S. Publication No. 2002/0035053A1 published in the name of Demeyere et al. on Mar. 21, 2002.

Any type of perfume can be incorporated into the composition of the present invention. The preferred perfume ingredients are those suitable for use for application on fabrics and garments. Typical examples of such preferred ingredients are given in U.S. Pat. No. 5,445,747, issued Aug. 29, 1995 to Kvietok et al.

When long lasting fragrance odor on fabrics is desired, it is preferred to use at least an effective amount of perfume ingredients which have a boiling point of about 240° C. or higher and preferably of about 250° C. or higher. Nonlimiting examples of such preferred ingredients are given in U.S. Pat. No. 5,500,138, issued Mar. 19, 1996 to Bacon et al. It is also preferred to use materials that can slowly release perfume ingredients after the fabric is treated by the wrinkle control composition of this invention. Non-limiting examples of materials of this type are disclosed in U.S. Pat. No. 5,531,910, issued to Severns et al. on Jul. 2, 1996.

Other perfume ingredients can act as solvents. In some cases this can help facilitate the incorporation of other perfume or oil ingredients into the overall composition. A particularly good example here is benzyl alcohol. Benzyl alcohol has limited water solubility (clogP of about 1.2) and has been shown to help incorporate other perfume ingredient mixes into these compositions.

### Branched Hydrocarbon:

An effective amount of a hydrocarbon with sufficient branching is utilized which provides a stable, preferably well dispersed, more preferably translucent, and even more preferably clear, highly aqueous microemulsion wrinkle reduction composition. The hydrocarbon component may be saturated or unsaturated and preferably has a carbon content and structure so as to be a liquid at room temperature as opposed to being volatile or a solid.

One non-limiting example of a suitable branched hydrocarbon is ISOPAR V available from ExxonMobile Incorporated of Irving, Tex. Another suitable branched hydrocarbon is PERMETHYL 102A available through Presperse Incorporated of Somerset, N.J.

The branched hydrocarbons are used at an appropriate level to make a preferably clear, stable microemulsion mixture in conjunction with the water soluble quaternary surfactant and preferably perfume components. The branched hydrocarbon may be incorporated into the refresher spray separate from or pre-mixed in conjunction with perfume components.

Other optional, but desirable ingredients which may optionally be used in the present invention include nonionic surfactants, buffering agents, odor control agents, perfume microcapsules, cyclodextrin, low molecular weight polyols, metal salts, antibacterial and preservative agents, pH adjustment agents, as well as other optional ingredients:

### Nonionic Surfactants:

Examples of optional, but preferred nonionic surfactants are SURFYNOL 465, SURFYNOL 104 (2,4,7,9-tetramethyl-5-decyne-4,7-diol), and mixtures of the two. A preferred mixture is 3:1 SURFYNOL 465 to SURFYNOL 104. The SURFYNOL surfactants are available from Air Products and Chemicals, Incorporated of Allentown, Pa.

Another preferred nonionic class of surfactants are alkly polyglycoside surfactants. Examples of these surfactants are GLUCOPON 215, PLANTAREN 2000 N UP and GLUCOPON 425 and the like. These surfactants are available thru Cognis Oleochemicals of Selangor, Malaysia. These surfactants are particularly useful when the composition pH is targeted away from neutral (pH 7) as they are stable across a broad range of pH's.

Another nonionic surfactant group that can be used when the product pH is at or near 7, are the SILWET silicone polyethers. Nonlimiting examples of these silicone polyethers are the SILWET® materials which are available from GE Silicones. Representative SILWET® silicone polyethers which contain only ethyleneoxy (C₂H₄O) groups are as follows:

| | Average Molecular |
|---|---|
| | Weight (“MW”) in |
| Name | Daltons |
| L-7608 | 600 |
| L-7607 | 1,000 |
| L-77 | 600 |
| L-7605 | 6,000 |
| L-7604 | 4,000 |
| L-7600 | 4,000 |
| L-7657 | 5,000 |
| L-7602 | 3,000 |
| L-7622 | 10,000 |
| L-8600 | 2,100 |
| L-8610 | 1,700 |
| L-862 | 2,000 |

Nonlimiting examples of SILWET® silicone polyethers which contain both ethyleneoxy (C₂H₄O) and propyleneoxy (C₃H₆O) groups are as follows:

| | Average MW in | |
|---|---|---|
| Name | Daltons | EO/PO ratio |
| L-720 | 12,000 | 50/50 |
| L-7001 | 20,000 | 40/60 |
| L-7002 | 8,000 | 50/50 |
| L-7210 | 13,000 | 20/80 |
| L-7200 | 19,000 | 75/25 |
| L-7220 | 17,000 | 20/80 |

Nonlimiting examples of SILWET® silicone polyethers which contain only propyleneoxy (C₃H₆O) groups are as follows:

| | Average MW in |
|---|---|
| Name | Daltons |
| L7500 | 3,000 |
| L7510 | 13,000 |
| L7550 | 300 |
| L8500 | 2,800 |

Preferred SILWETS® aid in color restoration when included in the composition in a sufficient concentration and can also provide softness, which is especially preferred when a silicone polymer leaves a rough feeling on the surface of the fabric. Nonlimiting examples of preferred SILWETS® include L77, L7001, L7200, L7087 and, particularly, L-7600.

Some nonlimiting preferred Dow Corning® silicone polyethers include Dow Corning® DC Q2-5247, (dimethyl, methylhydroxypropyl, ethoxylated propoxylated siloxane, primarily [CAS# 68937-55-3] comprised of siloxane, EO, and PO. Other nonlimiting examples of silicone polyethers useful in the present invention include the following compounds available from Dow Corning®: 193, 112, 8600, FF-400 Fluid, Q2-5220, Q4-3667, PP 5495, as well as compounds available from Toray Dow Coming Silicone Co., Ltd. known as SH3771C, SH3772C, SH3773C, SH3746, SH3748, SH3749, SH8400, SF8410, and SH8700, KF351 (A), KF352 (A), KF354 (A), and KF615 (A) of Shin-Etsu Chemical Co., Ltd., TSF4440, TSF4445, TSF4446, TSF4452 of Toshiba Silicone Company. Another nonlimiting example is SLM 21200 from Wacker of Germany.

Some silicone polyethers (especially the more hydrophobic versions) may require additional emulsifying agents to make a stable spray composition. Such emulsifying agents are typically anionic, nonionic, cationic, amphoteric, or zwitterionic surfactants or mixtures thereof. Typically emulsifying agents and surfactants can also act as spreading agents on the fabric to spread out active ingredients such as the silicone polymers.

Typically, the minimum levels of the nonionic surfactant are at least about 0.01%, preferably at least about 0.05%, more preferably at least about 0.1% while typical maximum levels of nonionic surfactant are up to about 5%, preferably less than about 3% and more preferably less than about 1.5%.

### Optional Buffering Agents:

Buffering agents may be incorporated into the invention to help control the pH of the product during making and in use. If the product is formulated at an alkaline pH, and sprayed during use, a buffer in the preferred alkaline pH range can help prevent pH drop as a result of mixing with carbon dioxide from the air during spraying. Holding the pH at a targeted value can also help with neutralizing soils or malodors on fabric. Any suitable buffer, organic or inorganic, for the desired product pH can be used, providing at the level used it affords the mixture adequate stability. Preferred alkaline buffers include, but are not limited to, Triethanolamine, glycine, arginine, carbonate salts, bicarbonate salts such as sodium bicarbonate, and the like.

### Optional Odor Control Agents:

Optionally, an effective amount of malodor control agents may be used if desired to provide additional malodor capturing/sequestering effects.

The compositions for odor control are of the type disclosed in U.S. Pat. Nos.: 5,534,165; 5,578,563; 5,663,134; 5,668,097; 5,670,475; and 5,714,137.

### Perfume Microcapsules:

In one embodiment, the perfume comprises a perfume microcapsule. Suitable perfume microcapsules and perfume nanocapsules include those disclosed in: U.S. Publication Nos.: 2003/215417 A1; US 2003/216488 A1; US 2003/158344 A1; US 2003/165692 A1; US 2004/071742 A1; US 2004/071746 A1; US 2004/072719 A1; US 2004/072720 A1; US 2003/203829 A1; US 2003/195133 A1; US 2004/087477 A1; US 2004/0106536 A1. Also those disclosed in U.S. Pat. No.: 6,645,479; U.S. Pat. No. 6,200,949; U.S. Pat. No. 4,882,220; U.S. Pat. No. 4,917,920; U.S. Pat. No. 4,514,461; U.S. Pat. No. RE 32713; U.S. Pat. No. 4,234,627; and EP 1,393,706 A1. For purposes of the present invention, the term “perfume microcapsules” describes both perfume microcapsules and perfume nanocapsules. In another embodiment, the perfume comprises a perfume microcapsule as described above and unencapsulated perfume.

### Cyclodextrin:

As used herein, the term “cyclodextrin” includes any of the known cyclodextrins such as unsubstituted cyclodextrins containing from six to twelve glucose units, especially, alpha-cyclodextrin, beta-cyclodextrin, gamma-cyclodextrin and/or their derivatives and/or mixtures thereof. The alpha-cyclodextrin consists of six glucose units, the beta-cyclodextrin consists of seven glucose units, and the gamma-cyclodextrin consists of eight glucose units arranged in donut-shaped rings. The specific coupling and conformation of the glucose units give the cyclodextrins a rigid, conical molecular structures with hollow interiors of specific volumes. The unique shape and physical-chemical properties of the cavity enable the cyclodextrin molecules to absorb (form inclusion complexes with) organic molecules or parts of organic molecules which can fit into the cavity. Many odorous molecules can fit into the cavity including many malodorous molecules and perfume molecules. Therefore, cyclodextrins, and especially mixtures of cyclodextrins with different size cavities, can be used to control odors caused by a broad spectrum of organic odoriferous materials, which may contain reactive functional groups. The complexation between cyclodextrin and odorous molecules occurs rapidly in the presence of water. However, the extent of the complex formation also depends on the polarity of the absorbed molecules. In an aqueous solution, strongly hydrophilic molecules (those which are highly water-soluble) are only partially absorbed, if at all. Therefore, cyclodextrin does not complex effectively with some very low molecular weight organic amines and acids when they are present at low levels on wet fabrics. As the water is being removed however, e.g., the fabric is being dried off, some low molecular weight organic amines and acids have more affinity and will complex with the cyclodextrins more readily.

The cavities within the cyclodextrin in the solution compositions described herein should remain essentially unfilled (the cyclodextrin remains uncomplexed) while in solution, in order to allow the cyclodextrin to absorb various odor molecules when the solution is applied to a surface. Non-derivatised (normal) beta-cyclodextrin can be present at a level up to its solubility limit of about 1.85% (about 1.85 g in 100 grams of water) at room temperature. Beta-cyclodextrin is not preferred in compositions which call for a level of cyclodextrin higher than its water solubility limit. Non-derivatised beta-cyclodextrin is generally not preferred when the composition contains surfactant since it affects the surface activity of most of the preferred surfactants that are compatible with the derivatised cyclodextrins.

For controlling odor on fabrics, the composition is preferably used as a spray. It is preferable that the usage compositions of the present invention contain low levels of cyclodextrin so that a visible stain does not appear on the fabric at normal usage levels. Preferably, the solution used to treat the surface under usage conditions is virtually not discernible when dry. Typical levels of cyclodextrin in usage compositions for usage conditions are from about 0.01% to about 5%, preferably from about 0.1% to about 4%, more preferably from about 0.5% to about 2% by weight of the composition. Compositions with higher concentrations can leave unacceptable visible stains on fabrics as the solution evaporates off of the fabric. This is especially a problem on thin, colored, synthetic fabrics, in order to avoid or minimize the occurrence of fabric staining, it is preferable that the fabric be treated at a level of less than about 5 mg of cyclodextrin per gram of fabric, more preferably less than about 2 mg of cyclodextrin per gram of fabric. The presence of the surfactant can improve appearance by minimizing localized spotting.

### Low Molecular Weight Polyols:

Low molecular weight polyols with relatively high boiling points, as compared to water, such as ethylene glycol, propylene glycol, and/or glycerol are preferred optional ingredients for improving odor control performance of the composition of the present invention when cyclodextrin is present. Not to be bound by theory, it is believed that the incorporation of a small amount of low molecular weight glycols into the composition of the present invention enhances the formation of the cyclodextrin inclusion complexes as the fabric dries.

It is believed that the polyols' ability to remain on the fabric for a longer period of time than water, as the fabric dries allows it to form ternary complexes with the cyclodextrin and some malodorous molecules. The addition of the glycols is believed to fill up void space in the cyclodextrin cavity that is unable to be filled by some malodor molecules of relatively smaller sizes. Preferably the glycol used is glycerin, ethylene glycol, propylene glycol, diethylene glycol, dipropylene glycol or mixtures thereof, more preferably ethylene glycol and/or propylene glycol. Cyclodextrins prepared by processes that result in a level of such polyols are highly desirable, since they can be used without removal of the polyols.

Some polyols, e.g., dipropylene glycol, are also useful to facilitate the solubilization of some perfume ingredients in the composition of the present invention.

Typically, glycol is added to the composition of the present invention at a level of from about 0.01% to about 3%, by weight of the composition, preferably from about 0.05% to about 1%, more preferably from about 0.1% to about 0.5%, by weight of the composition. The preferred weight ratio of low molecular weight polyol to cyclodextrin is from about 2:1,000 to about 20:100, more preferably from about 3:1,000 to about 15:100, even more preferably from about 5:1,000 to about 10:100, and most preferably from about 1:100 to about 7:100.

### Metal Salts:

Optionally, the present invention can include metallic salts for added odor absorption and/or antimicrobial benefit for the cyclodextrin solution when cyclodextrin is present. The metallic salts are selected from the group consisting of copper salts, zinc salts, and mixtures thereof.

When metallic salts are added to the composition of the present invention they are typically present at a level of from about 0. 05% to about 5%, preferably from about 0.1% to about 3%, more preferably from about 0.2% to about 2% by weight of the usage composition. When zinc salts are used as the metallic salt, and a clear solution is desired, it may be necessary to adjust the pH of the solution to less than about 7 in order to keep the solution clear.

When any of the odor control agents are added to the compositions of the present invention, they are typically present at a level of from about 0.01% to about 5%; preferably from about 0.1% to about 3%, and more preferably from about 0.2% to about 2% by weight of the composition.

### Antibacterial and Preservative Agents:

Optionally, the refresher composition of the present invention comprises an effective amount of antimicrobial active, to kill, or reduce the growth of microbes, wherein the amount of antimicrobial active when used is preferably from about 0.001% to about 0.5%, more preferably from about 0.002% to about 0.2%, even more preferably from about 0.005% to about 0.1%, by weight of the usage composition. The effective antimicrobial active can function as disinfectants/sanitizers, and is useful in providing protection against organisms that become attached to the fabrics.

Examples of additional preservatives include the hydantoin chemistry based materials. Suitable examples of hydantoin chemistry based materials include include the dimethylol-5,5-dimethylhydantoin (DMDMH) based preservatives as exemplified by Dantogard 2000 and Dantogard Plus available from Lonza Group Ltd. of Basel, Switzerland.

Other non-limiting examples of suitable preservatives that could be used alone or in combination are 2-Methyl-4-isothiazolin-3-one and 2-Methyl-3(2H) isothiazolin exemplified by Neolone M-10 products as supplied by Rohm & Haas; 1,2 Benzisothiazolin 3-one based materials exemplified by Koralone B-119 by Rohm & Haas; mixtures of Methylisothiazolinone and Benzisothiazolinone compounds exemplified by Acticide MBS by Thor/Actichem; mixtures of Methylchloroisothiazolinone and Methylisothiazolinone as exemplified by Kathon GC supplied by Rohm & Haas; and 1,2-Benzisothiazolin-3-one exemplified by Proxel GXL as supplied by Arch Chemicals.

### pH Adjustment Agents:

For lowering the composition pH to a desired level, acidic materials can be utilized. Non-limiting examples of suitable acids are small organic acids, like citric acid and inorganic acids like sulfuric or hydrochloric acid. Preferably the acid used, and final pH of the composition, is chosen to give a stable mix both chemically and physically.

For raising the composition pH to a desired level, basic materials can be utilized. Non-limiting examples of suitable bases are typically low molecular weight inorganic bases like sodium hydroxide. Preferably the base used, and final pH of the composition, is chosen to give a stable mix both chemically and physically. Preferably the compositions of the present invention have a pH of from about 3 to about 11, preferably from about 4 to about 10, and more preferably from about 5 to about 9.

### Other Optional Ingredients:

The composition of the present invention can optionally contain adjunct odor-controlling materials, chelating agents, antistatic agents, softeneing agents, insect and moth repelling agents, colorants, antioxidants, chelants, bodying agents, drape and form control agents, smoothness agents, wrinkle control agents, sanitization agents, disinfecting agents, germ control agents, mold control agents, mildew control agents, antiviral agents, drying agents, stain resistance agents, soil release agents, malodor control agents, fabric refreshing agents and freshness extending agents, chlorine bleach odor control agents, dye fixatives, dye transfer inhibitors, color maintenance agents, optical brighteners, color restoration/rejuvenation agents, anti-fading agents, whiteness enhancers, anti-abrasion agents, wear resistance agents, fabric integrity agents, anti-wear agents, anti-pilling agents, defoamers and anti-foaming agents, UV protection agents for fabrics and skin, sun fade inhibitors, anti-allergenic agents, enzymes, water proofing agents, fabric comfort agents, shrinkage resistance agents, stretch resistance agents, stretch recovery agents, functional microcapsules containing active materials such as perfumes, silicones, skin care agents, glycerin, and natural actives such as aloe vera, vitamin E, shea butter and the like, and mixtures thereof in addition to the silicone molecules. The total level of optional ingredients is low, preferably less than about 5%, more preferably less than about 3%, and even more preferably less than about 2%, by weight of the usage composition. These optional ingredients exclude the other ingredients specifically mentioned hereinbefore. Incorporating adjunct odor-controlling materials can enhance the capacity of the cyclodextrin to control odors as well as broaden the range of odor types and molecule sizes which can be controlled. Such materials include, for example, metallic salts, water-soluble cationic and anionic polymers, zeolites, water-soluble bicarbonate salts, and mixtures thereof.

### Carrier:

The preferred carrier of the present invention is water. The water which is used can be distilled, deionized, or tap water. Water is the main liquid carrier due to its low cost, availability, safety, and environmental compatibility. Aqueous solutions are also preferred when wrinkle control and odor control benefits are desired.

Water is very useful for fabric wrinkle removal or reduction. Not wishing to be bound by theory, it is believed that water breaks many intrafiber and interfiber hydrogen bonds that keep the fabric in a wrinkled state. It also swells, lubricates and relaxes the fibers to help the wrinkle removal process.

Water also serves as the liquid carrier for the cyclodextrins, and facilitates the complexation reaction between the cyclodextrin molecules and any malodorous molecules that are on the fabric when it is treated. The dilute aqueous solution also provides the maximum separation of cyclodextrin molecules on the fabric and thereby maximizes the chance that an odor molecule will interact with a cyclodextrin molecule. It has recently also been discovered that water has an unexpected odor controlling effect of its own. It has been discovered that the intensity of the odor generated by some polar, low molecular weight organic amines, acids, and mercaptans is reduced when the odor-contaminated fabrics are treated with an aqueous solution. Not to be bound by theory, it is believed that water solubilizes and depresses the vapor pressure of these polar, low molecular weight organic molecules, thus reducing their odor intensity.

The level of liquid carrier in the compositions of the present invention is typically at least about 80%, preferably greater than about 90%, more preferably greater than about 95%, by weight of the composition. When a concentrated composition is used, the level of liquid carrier is typically about 50% or less by weight of the composition, preferably about 40% or less by weight of the composition, and more preferably about 30% or less by weight of the composition.

### Water Soluble Solvent:

Optionally, in addition to water, the carrier can contain a low molecular weight organic solvent that is substantially soluble in water. Non-limiting examples are ethanol, n-propanol, isopropanol, n-butanol, tert-butyl alcohol deodorized acetone, acetone, and the like, and mixtures thereof. Low molecular weight alcohols can help the treated fabric to dry faster. Other solvents can also be used such as ethers of ethylene glycol and propylene glycol (e.g., ethylene glycol monohexyl ether) and glycols such as glycerin, propylene glycol, dipropylene glycol, ethylene glycol, and the like. Other non-limiting examples include 1,3-propanediol, diethylene glycol, 1,2,3-propanetriol, propylene carbonate, phenylethyl alcohol, 2-methyl 1,3-propanediol, hexylene glycol, sorbitol, polyethylene glycols, 1,2-hexanediol, 1,2-pentanediol, 1,2-butanediol, 1,4 butanediol, 1,4-cyclohexanedimethanol, pinacol, 1,5-hexanediol, 1,6-hexanediol, 2,4-dimethyl-2,4-pentanediol, 2,2,4-trimethyl-1,3-pentanediol (and ethoxylates), 2-ethyl-1,3-hexanediol, phenoxyethanol (and ethoxylates), other glycol ethers such as butyl carbitol and dipropylene glycol n-butyl ether, ester solvents such as dimethyl esters of adipic, glutaric, and succinic acids, and mixtures thereof. The optional solvent is also useful in the solubilization of some shape retention polymers and some silicone polymers described hereinbefore. The optional water soluble low molecular weight solvent can be used at a level of up to about 8%, typically from about 0.05% to about 8%, preferably from about 0.1% to about 5%, more preferably from about 0.2% to about 3%, by weight of the total composition. Factors that need to be considered when a high level of solvent is used in the composition are cost, odor, flammability, and environmental impact. Flammable organic solvents are not preferred if the intended use of the composition is to dispense it (for example, spray) into an automated clothes dryer.

### B. Article of Manufacture

The present invention may also comprise a composition and a dispenser for dispensing the composition. Non-limiting examples of suitable dispensers for dispensing or containing the composition include sprayers such as self-pressurized spray containers (such as aerosol containers), trigger sprayers, dispensers such as those disclosed in U.S. Pat. No. 7,059,065 issued to Gerlach et al. on Jun. 13, 2006; U.S. Pat. No. 7,043,855 issued to Heilman et al. on May 16, 2006; U.S. Publication No. 2004/0143994 published in the name of Barron et al. on Jul. 29, 2004; and U.S. Publication No. 2004/0123489 published in the name of Pancheri et al. on Jul. 1, 2004, and the like; as well as nebulizers; substrates which carry/contain the composition non-limiting examples of which include a substrate such as a wipe or pad, or roller (one non-limiting example of which is a lint roller); or combination thereof. If desired, the compositions may be dispensed directly to the fabric to be treated.

An effective amount of the liquid composition is preferably sprayed onto fabrics, particularly clothing. When the composition is sprayed onto fabric an effective amount should be deposited onto the fabric with the fabric becoming damp or totally saturated with the composition, typically from about 0.05% to about 150%, preferably from about 1.0% to about 75%, more preferably from about 2% to about 25% by weight of the fabric sprayed. Once it has been sprayed the fabric is optionally and for purposes of wrinkle removal preferably tensioned. Tensioning can be applied by mechanical means such as by weights, pulleys, etc., or by hand in a tug & pull approach. The fabric is typically tensioned perpendicular to the wrinkle, or along the vertical axis of a garment if it hangs using gravity as a tensioning force. The fabric can also be smoothed and/or shaken by hand after it has been sprayed to remove wrinkles.

Alternatively or in addition to, the compositions may be added and/or dispensed directly into a fabric treatment appliance non-limiting examples of which include a fabric washing apparatus (one non-limiting example of which is a washing machine); a fabric drying apparatus (one non-limiting example of which is a tumble dryer); a fabric refreshing apparatus (one non-limiting example of which is disclosed in U.S. Pat. No. 6,726,186 issued to Gaaloul et al. on Apr. 27, 2004; U.S. Pat. No. 6,893,469 issued to Van Hauwermeiren et al. on May 17, 2005; and U.S. Pat. No. 6,840,068 issued to Pasin et al. on Jan. 11, 2005.

### 1. Self Pressurized Spray Product

In one non-limiting embodiment, the present invention may be a self-pressurized spray product:

(1) A dispensing container, capable of sustaining the desired pressure inside the container without bursting or deforming;

(2) a propellant;

(3) An aqueous treatment formulation to provide benefits such as de-wrinkling and de-odorizing containing a water soluble dialkly quat, an oil comprising a perfume and/or hydrocarbon, and a sufficiently branched hydrocarbon and optional ingredients as described above;

(4) a valve, nozzle orifice, and actuator assembly which, when actuated, delivers a uniformly aerosolized spray cone with even surface coverage.

### Pressurized Dispensing Container

The dispensing container of the present invention can be any suitable container for holding ingredients under the pressure created by a propellant, typically referred to as an aerosol container. The design of such containers in the form of metal cans is well known, including both steel (tinplate) and aluminum aerosol containers. More recently, even plastic containers have been developed which can be used to maintain the pressure created by a propellant inside the container.

As an aerosol container is a pressurized container, specifications for such containers are regulated in many countries according to the pressure being contained. This has resulted in a number of standard industry specifications for aerosol containers. For example, standard aerosol containers in the United States are typically classified as nonspecification, 2P or 2Q containers. These specifications designate minimum buckle and burst pressures and a minimum wall thickness for the containers. For instance, aerosol products that exhibit a pressure of less than 1070 kilopascals (“kPa”) at 54.5° C. (130° F.) are classified as nonspecification containers and are typically not identified. Aerosol systems that exhibit a pressure at 54.5° C. between 1070 kPa and 1200 kPa are required to use a can construction having a 2P specification or higher. Aerosol systems that exhibit a pressure at 54.5° C. between 1200 kPa and 1340 kPa are typically required to use a can construction having a 2Q specification or higher. Similar standards exist in Europe with alternative designations including the 12 bar and 18 bar can standards. These industry standards have been developed to maintain tight control on the construction of aerosol containers.

For the present invention, aluminum cans meeting a 2Q specification are desirable. Such cans can be obtained from numerous manufacturers of aerosol containers, including, but not limited to, CCL Container Aerosol Division, of Hermitage, Pa. or Exal Container of Youngstown, Ohio.

The dispensing container can be of any suitable shape. Aerosol cans for example of a cylindrical shape are well known in the industry. In fact, industry standard can dimensions have also been established providing a range of stock can sizes. These cans are typically specified according to the overall diameter and the overall height of the can. Necked cans, wherein the container tapers inwardly towards the upper portion of the can, are commonly used. Cans with shoulders may also be used. The container can have numerous shapes in different embodiments, but a necked cylindrical can shape tends to be ergonomically desirable. In one non-limiting embodiment of the present invention, a necked cylindrical can shape having a 53 mm diameter and a height of about 205 mm may be used.

Most cans include coatings or liners to help protect the container from corrosion and the product from any possible chemical reaction with the container itself. Even slight reactions between the product in the container and the container metallurgy can give rise to fragrance changes, color changes, loss of chemical activity of critical components, and even over-pressure conditions through reactions which create additional gas. Hence, the industry has developed a range of coatings and liners to prevent such interactions. These include but are not limited to enamels and liners made from the following kinds of resins: acrylic, maleic, polyamide imide, alkyd, vinyl, polybutadiene, phenolic, epoxy-amine, epoxy-ester, epoxy-phenolic, oleoresin, and others. The choice of coating or liner depends on the product characteristics and the metallurgy of the aerosol container. One embodiment which uses a polyamide imide liner coating is sold as PAM 8460N, available from PPG Packaging Coatings, HOBA Division, of Grabenstrabe, Germany.

### Propellant

The propellant of the present invention is capable of sustaining a full can pressure at 70° F. (21° C.) above 50 psig (446 kPa) and above 40 psig (377 kPa) after 75% of the formula has been used. The propellant can be selected from among the numerous propellants commonly used in the aerosol industry. These are typically classified as either liquefied gas propellants or compressed gas propellants. Suitable compressed gas propellants include, but are not limited to, compressed air, nitrogen, nitrous oxide, carbon dioxide, and mixtures thereof. Suitable liquefied gas propellants include, but are not limited to, hydrocarbon propellants such as propane, isobutane, isopropane, isobutene, n-butane, dimethyl ether (“DME”), and mixtures thereof, and hydrofluorocarbons such as HFC 152a and HFC 134a.

The choice of propellant is a major factor influencing the gas pressure inside the can which in turn influences the delivery rate and impact pressure associated with the spray upon actuation of the valve. In certain embodiments, liquefied gas propellants may be preferred over compressed gas propellants because they tend to better maintain the pressure inside the can throughout the use of the product, because as the liquid phase propellant boils off to maintain pressure as the gas volume of the can increases due to product consumption. If it is desired to control the level of Volatile Organic Compounds (VOC's) that are given off by a spray, compressed gas like Nitrogen may be desired.

Propellants are commonly mixed to achieve the desired can pressure. Mixtures of propellants can contain propane, isobutane, and n-butane. In various embodiments of the present invention, mixtures of propane and isobutane having a vapor pressure at 70° F. between about 70 psig and about 100 psig may be desirable. In one non-limiting embodiment of the present invention a common blend of propane and isobutane referred to as Aeron A85, and available from Diversified CPC International, Inc. of Channahon, Ill., USA, may be used. This blend comprises 68.9 mol % propane and 31.1 mol % isobutane and provides a vapor pressure at 70° F. of 85 psig.

Optionally, in cases where excessive interaction between the propellant and product needs to be avoided, barrier packaging systems have been developed to separate the propellant from the product inside the aerosol container. These include piston barrier packaging and bag-in-can packaging, such as the ABS® Advanced Barrier System available from CCL Container, Advance Monobloc Aerosol Division of Hermitage, Pa. In some embodiments, these barrier packaging approaches can be employed to obtain more consistent product properties throughout the usage period of the product.

### System

The self-pressurized refreshing article of the present invention may be used alone as a refreshing article or optionally, if desired, may be used in conjunction with a system for removing wrinkles and odors from fabric. For instance, in one non-limiting example the self-pressurized wrinkle and odor refreshing article may be used in conjunction with a laundry process to remove odors prior to laundering. For example, the self-pressurized wrinkle and odor refreshing article could be used in conjunction with a fabric washing appliance including but not limited to a washing machine wherein the fabric is treated with the self-pressurized wrinkle and odor refreshing article and then is laundered in a fabric washing machine. Alternatively, either before or after treatment with the self-pressurized wrinkle and odor refreshing article the fabric could be refreshed in a refreshing appliance including but not limited to a refreshing cabinet, one non-limiting example of which is disclosed in U.S. Pat. No. 6,726,186. If desired, the self-pressurized wrinkle and odor refreshing article may be used as part of pretreatment process to pretreat stains or particularly malodorous areas on fabric prior to laundering and/or refreshing. Additionally, if desired, either before or after treatment with the self-pressurized wrinkle and odor refreshing article, the fabric could be treated in a fabric article drying appliance, one non-limiting example of which is a tumble dryer.

Yet additionally, the self-pressurized refreshing article if desired may be used, sold, and/or grouped with other fabric treatment products to form part of a fabric treatment array of products which are useful for providing fabric treatment benefits without having to resort to a laundry washing process. For instance, in one non-limiting example, the self-pressurized refreshing article may be provided in conjunction with a product(s) for refreshing fabric and/or a product(s) for removing stains, and/or a color appearance enhancer product(s) (such as that disclosed in U.S. patent application Ser. Nos. 12/008,427 and 12/008504 both filed on Jan. 11, 2008) all of which may be applied to fabric without having to be applied as part of the laundry washing process. The array of fabric treatment products may be available in different forms. For instance, the refreshing product and/or the stain removal product may be in the form of a substrate such as a cloth, wipe, pad, sponge, tape (non-limiting examples of which would be a lint roller or a stain-removal pen) or in the form of a spray. Likewise, the color appearance enhancer product may be in the form of a spray or substrate.

### Tensioning

When refreshing a fabric article, it is advantageous and preferred to combine the product application with applied tension to reduce the amount of wrinkles in the fabric article. It is particularly advantageous to apply the tension during the time “window” wherein the wetted fabric has become/remains “mobile” (able to be stretched) and is not completely dry. The term “tension” as used herein refers to a force applied to the fabric to create stretching, pull or flattening of the fiber matrix. Tension can be applied in a non-uniform or uniform way. Examples of non-uniform tension include but are not limited to tumbling in a dryer and line-drying with wind. Uniform tensioning includes, but is not limited to, gravity, hand manipulation (e.g., tugging, smoothing, pulling) in a specific direction, ironing, application of weights or another mechanical tensioning system. The magnitude of the smoothing/wrinkle reduction benefit will be proportional to the nature, amount, and duration of the tension applied. Generally end results are better with uniform vs. non-uniform tensioning, with greater vs. lesser force.

The compositions of the present invention can also be used as ironing aids. An effective amount of the composition can be sprayed onto fabric and the fabric is ironed at the normal temperature at which it should be ironed. The fabric can either be sprayed with an effective amount of the composition, allowed to dry and then ironed, or sprayed and ironed immediately.

In a still further aspect of the invention, the composition can be sprayed onto fabrics by in an in-home de-wrinkling chamber containing the fabric to be de-wrinkled and/or optionally deodorized, thereby providing ease of operation. Conventional personal as well as industrial deodorizing and/or de-wrinkling apparatuses are suitable for use herein. Traditionally, these apparatuses act by a steaming process which effects a relaxation of the fibers alternately the fabrics may be sprayed with a refreshing composition and subsequently exposed to a heated and/or drying environment. Examples of home dewrinkling chambers include shower stalls. The spraying of the composition or compounds onto the fabrics can then occur within the chamber of the apparatus or before placing the fabrics into the chamber. Again, the spraying means should preferably be capable of providing droplets with a weight average diameter of from about 8 to about 100 μm, preferably from about 10 to about 50 μm. Preferably, the loading of moisture on fabrics made of natural and synthetic fibers is from about 0.05% to about 150%, preferably from about 1% to abut 75%, more preferably from about 2% to about 25% by weight of the fabric sprayed. Other conventional steps that can be carried out in the dewrinkling apparatus can be applied such as heating and drying. Preferably, for optimum benefit, the temperature profile inside the chamber ranges from about 30° C. to about 80° C., more preferably from about 40° C. to about 70° C., and even more preferably from about 50° C. to about 80° C. The preferred length of the drying cycle is from about 3 to about 60 minutes, more preferably from about 10 to about 30 minutes. The steaming step in the dewrinkling apparatus may also be eliminated if the composition is maintained at a temperature range from about 22° C. (about 72° F.) to about 76° C. (170° F.) before spraying.

### Self-Instructing Article of Commerce

The present invention also encompasses a self-pressurized spray dewrinkling and odor refreshing article of commerce. A set of instructions may be included in association with the article which directs the user to follow the method of removing wrinkles and malodors from textiles with the article. For instance, in one non-limiting embodiment, such instructions may direct the user to apply the spray to a wrinkled area on a textile. In another non-limiting embodiment, the instructions may direct the user to apply the spray to a wrinkled or malodorous area on a textile. In yet another embodiment, the instructions may direct the user to apply the spray from a distance of about 2 inches (5.08 cm) to about 8 inches (20.32 cm) from the surface of the fabric. In still another embodiment, the instructions may direct the user to focus the spray on the wrinkled or malodorous area and slowly move the spray outwardly from the center of the area. In yet another embodiment, the instructions may direct the user to apply a spray to a wrinkled area of the fabric and then apply tension to the fabric as discussed above.

Herein, “in association with”, when referring to such instructions, means the instructions are either directly printed on the article; directly printed on the packaging for the article; printed on a label attached to the packaging for the article; or presented in a different manner including, but not limited to, a brochure, print advertisement, electronic advertisement, broadcast or internet advertisements; and/or other media, so as to communicate the set of instructions to a consumer of the article.

Method of Treating Textiles with the Self-Pressurized Spray Wrinkle and Odor Refreshing Article of the Present Invention

The present invention also includes a method of use for wrinkle and odor refreshing on textiles with the self-pressurized spray article of the present invention. This includes actuating the spray article so that the spray stream contacts the wrinkle or malodorous area on the textile. The method of use may optionally include wiping, blotting, or laundering the textile after it is contacted by the article.

### Test Methods

### Wetting Index Test

The Wetting Index is a test that measures the wetting rate of a product on various fabrics. The test involves putting a drop of test product (water is the reference product) on a fabric sample and timing how long it takes for the drop of product to fully penetrate the fabric surface. The wetting index is defined as the time in seconds it takes a water control to fully penetrate the surface divided by the time it takes the test product. A bigger wetting index thus indicates better wetting and can be thought of as representing how many times faster the product wets than water.

The method consists of the following steps:
1) A standard 6″ diameter 2-piece embroidery ring/hoop is used to hold the fabric material. A fabric sample larger than the hoop is laid over the inner hoop so it is laying flat. The outer/secondary hoop is placed over the swatch and pushed down over the inner hoop wedging the fabric between the two hoops. This should leave the fabric sample in a flat condition held in place between the two hoops with slight tension.
2) The hoop with fabric is placed on a level surface, being careful not to let the fabric outside the hoop to be folded under the hoop when it is placed on the level surface. The intent is to have the fabric level (perpendicular or normal to the direction of gravity) for the testing.
3) A VWR 20 to 200 Micro liter pipette is mounted so the dispensing tip is ¼+ 1/16 inch above the fabric surface, with the pipette being perpendicular to the surface. The pipette is set to dispense a 30 μLiter drop.
4) To clearly view the drop penetration and determine the end point, a light source is mounted to illuminate the fabric at about a 45 degree angle to the surface.
5) To begin the test a 30 μLiter drop is dispensed from the pipette. As soon as the drop is dispensed and contacts the fabric a timer is started. The end point is defined when there is no free product left on the surface as determined by the extinction of visual surface reflectivity from the ambient light source. Reflection of the light off the product surface as a point (or points) of light is no longer observed, but just the fabric surface is seen. At this point the timer is stopped and the wetting time (T) is recorded.
6) The timing procedure is conducted with a Distilled water control, and the water wetting time is noted as T_{w}. The timing procedure is also conducted with the test product and the wetting time is noted as Tₚ.
7) The Wetting Index is calculated as WI=T_{w}/Tₚ.
   For testing reported herein, the following fabric samples were used:
   100% Cotton woven fabric: Style 400 Cotton Print Cloth available from Testfabrics, Inc., Middlesex, N.J.
   75% Polyester, 25% cotton woven fabric: Style PC 49 PolyCotton available from Empirical Manufacturing Company, Cincinnati Ohio.
   100% Polyester weave available from Empirical Manufacturing Company, Cincinnati Ohio.
   100% wool cloth available from Empirical Manufacturing Company, Cincinnati Ohio.

### Moisture Management Test

Use of the fabric refresher composition on fabrics results in modified moisture management properties of the treated fabric. The properties commonly used to assess overall moisture management capability include wetting time, absorption rate, maximum wetting radius, spreading speed and dynamism of one-way transport. The wetting rate is the parameter that initiates the process of moving moisture away from the skin to improve comfort. This measurement is easily made in the laboratory as noted in the wetting management test here.

The Moisture Management test is conducted similar to the Wetting Index test described above, but in this test the products are sprayed onto the fabric surface while they are in the holding hoop as a pre-treatment, and the pretreated fabric is allowed to dry a minimum of 2 hours. The product is sprayed onto the fabric with any appropriate sprayer device at a distance sufficient to get uniform coverage on the fabric. For aerosol containers and pressure trigger atomizing sprayers the spray distance is about 5 inches. 1 to 2 grams of product is applied to the 6″ hoop test area. Once the pretreated fabric is dry, the wetting time for a drop (30 μLiter) of distilled water is measured after being applied to the surface in a manner as described in the Wetting Index test. For a moisture management effect, the wetting time for a drop of water is faster after the fabric has been treated with the fabric refresher composition as compared to having been pretreated with water alone.

### Product pH After Spraying Test

This test measures the pH before and after spraying products to report a final sprayed pH and determine a Δ or change in pH as a result of spraying.

The pH of samples before and after spraying was measured using a VWR Symphony SP80PI pH meter with a gel 3-in-1 gel pH electrode available from VWR International of West Chester, Pa. Prior to use each day the meter was calibrated per the manufacturer's procedure using a minimum of two buffers that bracketed the range of pH's of the samples.

The pH of test samples is first measured neat, or as is, prior to spraying (Initial pH) and then 35 to 40 grams of the test sample is sprayed into a suitable plastic cup (compatible with the solution) at a distance of 6″ above the bottom of the cup, using a Calmar pressure trigger sprayer having a standard swirl chamber atomizer and dispensing approximately 1.0 to 1.5 cc per pull.

The trigger is pulled rapidly to facilitate best atomization. After completion of the spraying the final pH is measured. The procedure is repeated 5 times and averaged to get a representative initial pH and final pH after spraying.

The change in pH (ΔpH) is calculated as follows: ΔpH =(pH after spraying)−(Initial pH)

If ΔpH is positive then spraying increased the pH which may be undesirable for acidic products. If ΔpH is negative, then spraying decreased the pH which may be undesirable for alkaline products.

### Malodor Removal Test A

This test method is used to evaluate the effectiveness of a composition in reducing or removing malodor from fabrics. The test fabrics are first washed in a laundry washer using unscented laundry detergent and then dried in a laundry dryer. About 5 milliliters of a diluted synthetic body malodor composition is uniformly applied over an eight square inch area of each test fabric. The malodor-treated test fabrics are dried and then sealed in a bag and allowed to equilibrate overnight at ambient temperature. Qualified odor graders evaluate the initial malodor level of the malodor-treated test fabrics and assign a malodor grade according to the Malodor Evaluation Scale below. The malodor-treated test fabrics are then treated with equivalent amounts of the test compositions by spraying an effective amount of the test compositions (about 60% by weight) onto the test fabrics and allowing the test fabrics to dry. Once the test fabrics have dried, the qualified odor graders again evaluate the malodor level of the test fabrics and assign a malodor grade according to the Malodor Evaluation Scale below. Initial malodor grades and after-treatment malodor grades are recorded and the differences between the grades are calculated to establish the “Malodor Reduction” value.

### Malodor Evaluation Scale

0 No Malodor/Perfume Present
10 I Think There is Malodor/Perfume Present
25 Slight Malodor/Perfume Present
50 Moderate Malodor/Perfume Present
75 Strong Malodor/Perfume Present
100 Extremely Strong Malodor/Perfume Present

### Malodor Removal Test B

This test method is used to evaluate the effectiveness of a composition in reducing or removing malodor from fabrics. Panelists are given new garments to wear several times without laundering between wear occasions. Qualified odor graders evaluate the initial malodor level of the malodor-treated test fabrics and assign a malodor grade according to the Malodor Evaluation Scale above. The malodor-treated test fabrics are then treated with equivalent amounts of the test compositions by spraying an effective amount of the test compositions (about 2% to 5% by weight) onto the test garments and allowing the test garments to dry. Once the test garments have dried, the qualified odor graders again evaluate the malodor level of the test fabrics and assign a malodor grade according to the Malodor Evaluation Scale above. Initial malodor grades and after-treatment malodor grades are recorded and the differences between the grades are calculated to establish the “Malodor Reduction” value.

### Wrinkle Removal Test

This test method is used to evaluate the effectiveness of a composition in reducing or removing wrinkles from fabrics. The test fabrics are prepared by inducing either Smoothness Appearance (“SA”) (i.e.; laundry induced wrinkles) or Wrinkle Recovery (“WR”) (i.e.; wear induced wrinkles) according to the American Association of Textile Chemist and Colorists (“AATCC”) definitions. Qualified wrinkle graders evaluate the initial wrinkle level of the fabrics and assign a wrinkle score according to AATCC Test Method 128 and Test Method 143. The test fabrics are then treated with equivalent amounts of the test compositions by spraying the test compositions onto the test fabrics. Tensioning may be applied to the fabrics while they are wet by e.g. stretching, tugging and or smoothing the test fabrics to enhance wrinkle removal and allowing the test fabrics to dry. Once the test fabrics have dried, the qualified wrinkle graders evaluate the wrinkles again according to the AATCC scales.

### Microemulsion Particle Size Evaluation:

Average particle size is measured using a Malvern Zetasizer Nano ZS dynamic light scattering unit. All measurements are made at 22 C using a viscosity of 0.954 mPa-sec in clean disposable 10 mm cuvettes. A check National Institute of Standards and Technology (“NIST”) standard of 100 nm dispersed in 10 mmol NaCl is used to verify operation. Samples are allowed to equilibrate for 10 min.

The instrument sets attenuation and measurement position using internal optimization algorithm in operating software. Thirty runs of 20 sec each are averaged for a result. Each sample is run three times for a total of 3 results per sample. Samples can be filtered through a 0.5 micron filter prior to analysis to remove any large contaminants.

The average particle diameter for each sample is reported as the Z-Ave parameter by the Malvern software.

### EXAMPLES

TABLE 1

| | Composition | | | | | | | | |
|---|---|---|---|---|---|---|---|---|---|
| | A | B | C | D | E | F | G | H | I |
| Ingredients | Wt % | Wt % | Wt % | Wt % | Wt % | Wt % | Wt % | Wt % | Wt % |
| Arquad HTL8 MS (1) | 0.5 | 0.5 | 0.5 | | 0.5 | | | 0.5 | |
| Uniquat 22c50 (8) | | | | 0.8 | | | | | 0.5 |
| Barquat CME-35 (8) | | | | | | 0.5 | | | |
| Incrosoft AS-55 (7) | | | | | | | 0.5 | | |
| Silicone copolyol DC5247 (2) | | | | | 1.75 | | | | |
| Hydroxypropyl beta cyclodextrin | 1.0 | 1.0 | 1.0 | 1.0 | | 1.0 | 1.0 | | |
| Triethanolamine | 0.3 | 0.3 | 0.3 | 0.3 | | 0.3 | | 0.3 | 0.3 |
| Glycine | | | | | | | | | |
| Permethyl 102a (3) | 0.3 | 0.1 | 0.2 | | | | | 0.2 | |
| Isopar V (4) | | | | | | | 0.15 | | |
| Perfume | 0.15 | 0.15 | 0.1 | 0.44 | 0.44 | 0.44 | | See | See |
| | | | | | | | | example | example |
| Plantaren 2000 N UP (9) | | | | | | 1.0 | | | |
| PolyEthyleneGlycol | | | | | | | 0.5 | | |
| MonoStearate | | | | | | | | | |
| Surfynol 465 (5) | .075 | .075 | .075 | | | | | | |
| Surfynol 104pg (5) | .025 | .025 | .025 | | | | | | |
| Silwet 7608 (6) | | | | | 0.06 | | | | |
| Hexylene Glycol | | | | | 0.63 | | | | |
| PolyEthyleneGlycol 1450 | | | | | 0.2 | | | | |
| HCL | pH | pH | pH | | | | | | |
| | adjust | adjust | adjust | | | | | | |
| H2SO4 | | | | pH | | pH | pH | pH | pH |
| | | | | adjust | | adjust | adjust | adjust | adjust |
| NaOH | | | | | pH | | | | |
| | | | | | adjust | | | | |
| DTPA | | | | | 0.005 | | | | |
| DC 2310 (2) | | | | | 0.0004 | | | | |
| Dantogard Plus liquid (8) | | | | | 0.075 | | | | |
| Water | Balance | Balance | Balance | Balance | Balance | Balance | Balance | Balance | Balance |
| pH (neat) | 8.4 | 8.4 | 8.5 | 8.6 | 7.0 | 8.5 | 8.6 | 8.4 | 8.4 |

Composition

| | J | K | L | M |
|---|---|---|---|---|
| Ingredients | Wt % | Wt % | Wt % | Wt % |
| Arquad HTL8 MS (1) | 0.50 | | 0.50 | 0.50 |
| Uniquat 22c50 (8) | | 0.50 | | |
| Barquat CME-35 (8) | | | | |
| Incrosoft AS-55 (7) | | | | |
| Silicone copolyol DC5247 (2) | | | | |
| Hydroxypropyl beta cyclodextrin | 1.00 | 0.10 | 1.00 | 1.00 |
| Triethanolamine | 0.30 | 0.30 | 0.30 | 0.30 |
| Benzyl Alcohol | 0.25 | 0.20 | | |
| Permethyl 102a (3) | 0.20 | | 0.20 | 0.20 |
| Isopar V (4) | | | | |
| Perfume | 0.10 | 0.10 | 0.10 | 0.10 |
| Plantaren 2000 N UP (9) | | | | |
| Glucopon 215 UP (9) | | 0.10 | | |
| Surfynol 465 (5) | 0.06 | | 0.60 | 0.075 |
| Surfynol 104pg (5) | 0.02 | | 0.02 | 0.025 |
| Silwet 7608 (6) | | | | |
| NaHCO3 | | 0.10 | | |
| PolyEthyleneGlycol 1450 | | | | |
| HCL | pH | | pH | |
| | adjust | | adjust | |
| H2SO4 | | pH | | pH |
| | | adjust | | adjust |
| NaOH | | | | |
| DTPA | | | | |
| DC 2310 (2) | | | | |
| Dantogard Plus liquid (8) | | | | |
| Koralone B-119 (10) | | | 0.01 | |
| Neolone M10 (10) | | | | 0.01 |
| Water | Balance | Balance | Balance | Balance |
| pH (neat) | 8.5 | 8.9 | 8.5 | 8.5 |

(1) available from Akzo Nobel Chemical of Arnhem, Netherlands
(2) available from Dow Corning Corporation of Midland, Michigan
(3) available from Presperse Inc. of Somerset, New Jersey
(4) available from ExxonMobile Inc. of Irving, Texas
(5) available from Air Products and Chemicals, Inc. of Allentown, Pennsylvania
(6) available from GE Silicones of Wilton, Connecticut
(7) available from Croda Inc. of Edison, New Jersey
(8) available from Lonza Group Ltd. of Basel, Switzerland
(9) available from Cognis Oleochemicals of Selangor, Malaysia
(10) available from Rohm & Haas of Philadelphia, Pennsylvania

### Examples 1 and 2

### Malodor Removal and Wrinkle Removal

Composition A in Table 1 above is used. Hydroxypropyl beta cyclodextrin and TEA are added to purified water with stirring (Mix A). In a separate container Permethyl 102A is added to ARQUAD HTL8 MS with stirring. Perfume is then added and the mixture is stirred so that a single phase, clear mixture results (Mix B). In a separate container SURFYNOL 104 pg is mixed with SURFYNOL 465 in a 3:2 ratio with stirring (Mix C). Mix B is added to Mix A with stirring. After stirring for 10 minutes Mix C is then added. The pH of this mixture is adjusted to 8.4 with HCl and the final mixture is stirred an additional 10 minutes. The surface tension of this mixture is between approximately 26 and 29 dynes/cm.

Composition A is sprayed onto fabric from a 53×205 mm 2Q Aluminum Can with PAM Liner available from CCL Container, Hermitage, Pa., and allowed to evaporate. The can is fitted with a Moritz locking aerosol actuator available form SeaquistPerfect Dispensing LLC, Cary, Ill. The actuator is fitted with XT-96 valve type with 0.016 inch Valve Stem Orifice Diameter and 0.016 inch Valve Body Orifice Diameter. A DU3027 insert type with 0.012 inch Orifice Diameter is used. The can is filled to approx 60% volume with Composition A. Nitrogen is added through the valve stem to approximately 140 psi at 70° F. and approximately 155 psi at 130° F. When actuated, the product delivers a spray stream with a mass delivery rate of approximately 1.1 grams/sec. The level of coverage is uniform such that wet patches of product that are obvious to the consumer may be avoided with proper use. The ease and convenience of application is superior to conventional manual sprayers. Efficient malodor reduction and freshness delivery by the product is achieved and when the fabric is stretched, efficient wrinkle removal is also achieved as measured by the test methods described in the Test Methods section of this disclosure.

| | Dry | Malodor | Dry |
|---|---|---|---|
| Synthetic Body Odor | Fabric Odor | Reduction | Fabric Odor |
| Initial Malodor Grade: 55 | (Malodor) | Value | (Perfume) |
| Perfume I (Composition A) | 20 | 35 | 60 |
| Perfume II (Composition B) | 10 | 45 | 55 |
| Perfume III (Composition B) | 15 | 40 | 55 |

### WR Wrinkle

| | Delta WR (Final Grade-Initial Grade) |
|---|---|
| Composition A, Garment A, | 2.4 |
| Composition A, Garment B | 1.4 |

### Example 3

### Wrinkle Removal Test

Three different fabrics are evaluated for wrinkle removal using the SA wrinkle test method. Per the method outlined above, 100% cotton Capri pants, 55/40 Poly/Cotton white ladies woven shirt, and 100% cotton woven blue cotton shirt are pre-wrinkled. The garments are sprayed with uniform coverage on one side using a pressure trigger hand sprayer from Calmar. The garments are then subsequently tensioned by hand with tugging and pulling. The amount sprayed on the Capri pants, white poly/cotton shirts, and blue cotton shirts is approximately 10 grams, 5 grams, and 8 grams respectively. Three replicates of each garment is sprayed for each treatment. Initial wrinkle grades and final grades are recorded by 3 judges and the overall average delta in wrinkle grade (average final grade-average initial grade) for each garment type is calculated. A positive result for the overall average delta grade indicates wrinkle removal, with larger numbers representing better results (more wrinkle reduction).

| | White | Cotton | Blue |
|---|---|---|---|
| | Poly/Cotton shirt | Capri Pants | Cotton Shirt |
| | Overall average delta in | | |
| | wrinkle grade (Final-Initial | | |
| Composition D | 0.9 | 1.6 | 0.9 |
| Composition F | 0.8 | 1.6 | 0.9 |
| Commercial Wrinkle | 0.6 | 1.4 | 0.6 |
| Remover | | | |

These examples indicate that the present compositions can provide approximately a 1 to 1.5 improvement in wrinkle grade on these difficult garments. This is a level of improvement which is consumer noticeable. It should be noted that good wrinkle removal performance for these compositions is consistent with their good wetting index.

### Example 4

### Product pH After Spraying Test

Composition C is made as above and repeated again but without the Triethanolamine (TEA) buffer. The pH of the samples is adjusted to 7.8 with dilute Hydrochloric acid and the samples are left overnight to equilibrate.

### Results:

| Sample | Initial pH | pH After Spraying | Δ pH |
|---|---|---|---|
| Composition C | 7.7 | 7.7 | 0.0 |
| Composition C nil TEA | 7.7 | 7.5 | −0.2 |

The example above shows how adding a buffer can help lower the change in pH of an alkaline product when it is sprayed through the air.

### Example 5

### Wetting Index Test

Compositions C,D,E,F,G are made as above based on water soluble quats and evaluated in the Wetting Index Test using a cotton substrate. Three replicates (Reps) are run and then an average taken.

| | Distilled | | | | | |
|---|---|---|---|---|---|---|
| | Water | | | | | |
| Fabric | Wetting | Example C | Example D | Example E | Example F | Example G |
| Composition: | time | Wetting time | Wetting time | Wetting time | Wetting time | Wetting time |
| 100% Cotton | (seconds) | (seconds) | (seconds) | (seconds) | (seconds) | (seconds) |
| Rep 1 | 51 | 5 | 2 | 5 | 2 | 5 |
| Rep 2 | 49 | 5 | 2 | 5 | 2 | 5 |
| Rep 3 | 44 | 5 | 2 | 5 | 2 | 5 |
| Average | 48 | 5 | 2 | 5 | 2 | 5 |
| Wetting Index | 1.0* | 9.6 | 24.0 | 9.6 | 24.0 | 9.6 |

*The wetting index for water is 1.0 by default

### Example 6

### Wetting Index Test

Compositions C,D,E,F,G are made as above based on water soluble quats and evaluated in the Wetting Index Test using a Poly-cotton 75/25 substrate. Three replicates (Reps) are run and then an average taken.

| Fabric | Distilled | | | | | |
|---|---|---|---|---|---|---|
| Composition: | Water | | | | | |
| 75% | Wetting | Example C | Example D | Example E | Example F | Example G |
| Polyester/25% | time | Wetting time | Wetting time | Wetting time | Wetting time | Wetting time |
| Cotton | (seconds) | (seconds) | (seconds) | (seconds) | (seconds) | (seconds) |
| Rep 1 | 90 | 7 | 3 | 13 | 3 | 10 |
| Rep 2 | 96 | 8 | 4 | 13 | 3 | 12 |
| Rep 3 | 89 | 9 | 3 | 14 | 4 | 10 |
| Average | 91.7 | 8 | 2 | 13.3 | 3.3 | 10.7 |
| Wetting Index | 1.0* | 11.5 | 27.5 | 6.9 | 27.5 | 8.6 |

*The wetting index for water is 1.0 by default

### Example 7

### Wetting Index Test

Compositions C and D are made as above based on water soluble quats and evaluated in the Wetting Index Test using a polyester and wool substrates. Three replicates (Reps) are run and then an average taken. In this test the water droplet is very slow to penetrate so after 3 minutes the test is suspended and time noted as greater than 180 seconds.

| | 100% Polyester fabric | | | 100% Wool fabric | | |
|---|---|---|---|---|---|---|
| | Distilled | | | Distilled | | |
| | Water | | Example D | Water | | |
| | Wetting | Example C | Wetting | Wetting | Example C | Example D |
| | time | Wetting time | time | time | Wetting time | Wetting time |
| | (seconds) | (seconds) | (seconds) | (seconds) | (seconds) | (seconds) |
| Rep 1 | >180 | 49 | 12 | >180 | 6 | 2 |
| Rep 2 | >180 | 49 | 14 | >180 | 6 | 1 |
| Rep 3 | >180 | 47 | 12 | >180 | 5 | 1 |
| Average | >180 | 48.3 | 12.7 | >180 | 5.7 | 1.3 |
| Wetting Index | 1.0* | >3.7 | >14.2 | 1.0* | >24.0 | >135.0 |

*The wetting index for water is 1.0 by default

### Example 8

### Moisture Management Test

Two fabrics where moisture management is of special interest is on 100% Cotton and 100% Polyester. Compositions C and D are made as above based on water soluble quats and evaluated in the Moisture Management Test using polyester and cotton substrates. Four replicates (Reps) are run and then an average taken. In this test the water droplet on polyester is very slow to penetrate so after 5 minutes the test is suspended and time noted as greater than 300 seconds.

Wetting Time Assessment: Average time in seconds for water drop
complete absorption

| | Pretreatment Solution | | | |
|---|---|---|---|---|
| | | | | Commercial |
| | | Composition | Distilled | Wrinkle |
| Fabric | Composition C | D | Water | product |
| 100% polyester | 40.3 | 7.8 | >300 | 90.8 |
| 100% cotton | 3.0 | 3.0 | 81.3 | 15 |

The data in this example shows how pre-treating some fabrics with the disclosed compositions makes an impressive difference in how fast water is subsequently absorbed by the treated fabric surfaces.

### Example 9

### Microemulsion Particle Size Analysis

Compositions H and I are made having the same surfactant level and are similar to compositions C and D respectively but H and I had the cyclodextrin removed in order to get an accurate read as possible on the particle size of the microemulsion formed without possible interference from added cyclodextrin.

Three versions of Composition H are made up with different levels of perfume. The oil components in this case constitute a perfume having a clogP of 3.79 and the Permethyl 102A having a clogP of 6.58 as calculated by the LogP predictor from ChemSilo LLC. The oils are mixed together at room temperature with the Arquad HTL8 MS surfactant and then added to a Water & TEA mixture. Low shear prop mixing is utilized to achieve the final mixture. H₂SO₄ solution is titrated as a final step to adjust the pH to its final value.

Three versions of Composition I are made up with different levels of perfume. The oil component in this case constitutes the perfume having a C LogP of 3.79. The oil is mixed together at room temperature with the UNIQUAT 22c50 surfactant and then added to a Water & TEA mixture. Low shear prop mixing is utilized to achieve the final mixture. H₂SO₄ solution is titrated as a final step to adjust the pH to its final value.

The various versions of Composition H and Composition I are analyzed via the particle size method described herein and the average of 3 replicates for each sample is taken for the final reported diameter in nanometers.

| | | Average Particle |
|---|---|---|
| | | Diameter (Z-Ave) |
| Sample | Visual Appearance in 20 ml vile | nanometers |
| Composition H with | Very Clear and | 10.0 |
| 0.1% perfume | homogeneous | |
| Composition H with | Slightly gray/translucence | 94.8 |
| 0.2% perfume | and homogeneous | |
| Composition H with | Milky/Opaque and non- | 337.4 |
| 0.4% perfume | homogeneous (slight | |
| | separation observed) | |
| Composition I with | Clear and homogeneous | 114.5 |
| 0.1% perfume | | |
| Composition I with | Slightly gray/translucence | 128.9 |
| 0.2% perfume | and homogeneous | |
| Composition I with | Semi Opaque and | 135.0 |
| 0.4% perfume | homogeneous | |

The above data indicated that there is a limit on the amount of oil that the quaternary surfactant system can tolerate and maintain microemulsion properties. Above about an average particle size of 300 nm the system behaves as an macroemulsion with high opacity and non-homogeneity observed within 2 days.

### Example 10

### Static Control

This test demonstrates the characteristic static control of these compositions as demonstrated on a 100% Polyester shirt.

A representative 100% polyester ladies blouse, Lady Edwards™ style 5050-00 cut SN0414, is used in this testing. The front of the shirt is segmented into a left half and right half by putting a line of masking tape vertically down the center of the shirt. The sleeve on each side of the shirt is rubbed vertically on its respective front half of the shirt with 8 strokes over the length of the shirt to generate static on that side of the shirt. Each side is evaluated for the presence of static using a Greenlee non-contact voltage detector model GT-11 as described earlier. Next, using a pressure trigger hand sprayer and uniformly spraying over its respective side, the left half is sprayed with 6 grams composition C in Table 1 and the right half is sprayed with 6 grams of distilled water. After spraying, there was a 15 second wait before each side is evaluated for static while still damp. The shirt was allowed to dry for 90 minutes and then the sleeves are again rubbed on their respective side 8 times in an attempt to regenerate static. After rubbing, each side is evaluated for static again using the GT-11 non-contact voltage detector.

| Test Step | Voltage detector results |
|---|---|
| Left side of shirt rubbed with sleeve before treatment | Voltage detector reacts, indicating static |
| Right side of shirt rubbed with sleeve before treatment | Voltage detector reacts, indicating static |
| Left side sprayed with composition C and evaluated for static | Voltage detector does not react, indicating the absence |
| while damp | of noticeable static |
| Right side sprayed with distilled water and evaluated for | Voltage detector does not react, indicating the absence |
| static while damp | of noticeable static |
| After shirt dries, left side rubbed with sleeve | Voltage detector does not react, indicating the absence |
| | of noticeable static |
| After shirt dries, right side rubbed with sleeve | Voltage detector reacts, indicating static |

The results of this test show that although water can temporarily dissipate static that has previously formed on fabric, it will not prevent subsequent static build up. The quat based microemulsions will not only dissipate static that has formed on a fabric surface, but will prevent subsequent generation of static by virtue of the quat properties and excellent wetting coverage these compositions provide.

While particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention. All documents cited herein are in relevant part, incorporated by reference. The citation of any document is not to be construed as an admission that it is prior art with respect to the present invention.

What is claimed is:

1. A composition for treating fabrics, said composition comprising:
a) from about 0.01% to about 20% of a water soluble quaternary ammonium surfactant;
b) from about 0.001% to about 5% of a substantially water insoluble oil component;
c) optionally, from about 0.01% to about 5% of a nonionic surfactant;
d) optionally from about 0.01% to about 3% of a buffering agent;
e) optionally, from about 0.01% to about 5% of an odor control agent;
f) optionally, from about 0.001% to about 0.5% of an antimicrobial active;
g) optionally, a pH adjustment agent sufficient to achieve a pH from about 3 to about 11;
h) optionally, from about 0.001% to about 0.5% of a preservative;
i) optionally, from about 0.05% to about 8% of a substantially water soluble solvent; and
j) balance water;
such that the composition is homogeneous and stable.

2. The composition according to claim 1 wherein said composition further comprises a microemulsion with a mean particle size of about 300 nm or less.

3. The composition according to claim 2 wherein said composition is clear.

4. The composition according to claim 1 wherein said composition has a Wetting Index on cotton fabric of about 2.

5. A method for treating fabrics, said method comprising the steps of:
a) providing a composition wherein said composition comprises:
i) from about 0.01% to about 20% of a water soluble quaternary ammonium surfactant;
ii) from about 0.001% to about 5% of a substantially water insoluble oil component;
and
iii) balance water; and
b) applying said composition to fabric.

6. The method according to claim 5 wherein said composition is applied to said fabric by spraying.

7. The method according to claim 6 further comprising the step of tensioning said fabric either before or after the step of applying said composition to said fabric.

8. The method according to claim 5 wherein said fabric is placed in a washing machine either before or after the step of applying said composition to said fabric.

9. The method according to claim 5 wherein said fabric is placed in a refreshing appliance either before or after the step of applying said composition to said fabric.

10. The method according to claim 5 wherein said fabric is placed in a drying appliance before the step of applying said composition to said fabric.

11. A self-pressurized fabric refreshing article wherein said self-pressurized fabric refreshing article contains the composition of claim 1.

12. The self-pressurized fabric refreshing article of claim 11 wherein said self-pressurized fabric refreshing article is part of an array of products wherein said array of products further comprises a product for removing stains or a product for enhancing color appearance or both a product for removing stains and a product for enhancing color appearance.

13. Method for detecting the presence of static on fabrics, said method comprising the steps of:
a) providing a non contact AC voltage detector;
b) providing a fabric; and
b) running the non contact AC voltage detector over said fabric.
